(19) United States
(12) Patent Application Publication
(10) Pub. No.: US 2025/0043050 A1
(43) Pub. Date: Feb. 6, 2025

(54) CURABLE POLYMER, CURABLE COMPOSITION, PREPREG, MULTILAYER BODY, METAL CLAD LAMINATE AND WIRING BOARD

(71) Applicant: AGC Inc., Tokyo (JP)

(72) Inventors: Kazumi HASHIMOTO, Chiyoda-ku (JP); Tsukasa USUDA, Chiyoda-ku (JP); Yusuke YASU, Chiyoda-ku (JP); Takafumi IGARASHI, Chiyoda-ku (JP)

(73) Assignee: AGC Inc., Tokyo (JP)

(21) Appl. No.: 18/911,740

(22) Filed: Oct. 10, 2024

Related U.S. Application Data
(63) Continuation of application No. PCT/JP2023/014633, filed on Apr. 10, 2023.

(30) Foreign Application Priority Data
Apr. 28, 2022 (JP) 2022-074083

(51) Int. Cl. C08F 212/08; C08F 212/12; C08F 212/32; C08F 232/08; C08J 5/24; C09D 125/08; C09D 125/16; C09D 145/00; H05K 1/03

(52) U.S. Cl. CPC C08F 212/08; C08F 212/12; C08F 212/32; C08F 232/08; C08J 5/244; C09D 125/08; C09D 125/16; C09D 145/00; C08F 2800/10; C08F 2810/20; C08F 2810/50; C08J 2325/08; C08J 2325/16; C08J 2345/00; H05K 1/0366

(57) ABSTRACT

A curable polymer containing one or more type(s) of structural units (UX) represented by the following formula and which is for production of a prepreg, a metal clad laminate or a wiring board:

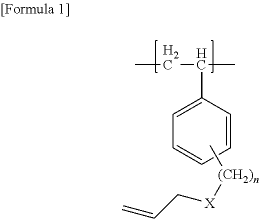

in which X is a single bond or an oxygen atom; the benzene ring optionally has a substituent other than the substituent in the above formula; and n is an integer of 0 or more.

### INCORPORATION BY REFERENCE

This application is based upon and claims the benefit of priority from Japanese patent application No. 2022-074083, filed on Apr. 28, 2022, and PCT application No. PCT/JP2023/014633 filed on Apr. 10, 2023, the disclosure of which is incorporated herein in its entirety by reference.

### BACKGROUND

The present disclosure relates to a curable polymer, a curable composition, a prepreg, a multilayer body, a metal clad laminate and a wiring board.

A wiring board (also referred to as a printed wiring board) is used in applications such as electrical and electronic devices. The wiring board can be manufactured, for example, as follows: A curable composition including a curable polymer, and, if necessary, additive(s) such as a flame retardant and an inorganic filler (also referred to as filler) is impregnated into a fibrous substrate, and the curable composition is (semi-) cured to produce a prepreg. One or more prepreg(s) are sandwiched between a pair of metal foils, and the resulting first temporary multilayer body is heated and pressed to produce a metal clad laminate. The metal foil on the outermost surface of the metal clad laminate is used to form a conductive pattern (also referred to as a circuit pattern) of wiring or the like. The outermost metal foil may be arranged only on one side of the first temporary multilayer body.

One or more prepreg(s) are further stacked on the resulting wiring board, which is sandwiched between a pair of metal foils, and the obtained second temporary multilayer body is heated and pressed to form a conductive pattern of wiring or the like using the metal foil on the outermost surface, thereby manufacturing a multilayer wiring board (also referred to as a multilayer printed wiring board). The outermost metal foil may be arranged only on one side of the second temporary multilayer body.

The heat-pressed product of the prepreg includes a fibrous substrate, a resin and an inorganic filler and is also referred to as a composite substrate. The composite substrate in the wiring board functions as an insulating layer.

The resin contained in the prepreg is a (semi-) cured product of the curable composition, and the resin contained in the composite substrate is a cured product of the curable composition.

Conventionally, a polyphenylene ether (modified PPE) oligomer (see formula (PPE-o) below) having a polymerizable functional group at each of both ends has been widely used as a curable polymer for a prepreg used in production of a wiring board.

In recent applications such as portable electronic devices, signals have become increasingly high-frequency as higher speeds and larger capacities of communication have been achieved. A wiring board used in such applications is required to have a reduced transmission loss in a high-frequency region, which mainly includes a conductor loss caused by the surface resistance of metal foil and a dielectric loss cause by the dielectric dissipation factor (D_{f}) of the composite substrate. For this reason, the resin contained in the composite substrate for the wiring board used in the above applications is required to have reduced dielectric loss in the high-frequency region. The dielectric dissipation factor (D_{f}) generally depends on frequency. Given the same material, the higher the frequency, the larger the dielectric dissipation factor (D_{f}) tends to be. The resin contained in the composite substrate preferably has a low dielectric dissipation factor (D_{f}) under high-frequency condition.

The dielectric dissipation factor (D_{f}) at 10 GHz of a polyphenylene ether (PPE) resin as a cured product of the modified polyphenylene ether (modified PPE) oligomer is around 0.002 to 0.003.

It is believed that higher speeds and larger capacities of communication are hereafter increasingly achieved, and it is believed that there is a need for a material capable of more reducing the dielectric dissipation factor (D_{f}) under high-frequency conditions of a resin included in a composite substrate.

The wiring board may be used in a relatively high-temperature environment. Even in this case, in order to ensure the reliability of the wiring board, the resin contained in the prepreg and the composite substrate preferably has a sufficiently high glass transition temperature (Tg).

Related art of the present disclosure includes Journal of Synthetic Organic Chemistry, Japan, vol. 27, No. 9, 1969, 858-862, Macromolecules, Vol. 32, No. 17, 1999, 5495-5500, Polymer, 59, 2015, 252-259, and Macromolecules, Vol. 32, No. 19, 1999, 6082-6087.

These Documents have reported partial synthesis of the curable polymer of the present disclosure. However, there is no description for applications of a prepreg, a metal clad laminate, and a wiring board, and no description for its dielectric properties.

The present disclosure has been made in view of the above circumstances, and an object thereof is to provide a curable polymer capable of producing a resin with sufficiently low dielectric dissipation factor (D_{f}) under high-frequency conditions and sufficiently high glass transition temperature (Tg), and a curable composition containing the same.

### SUMMARY

The present disclosure provides the following curable polymer, curable composition, prepreg, multilayer body, metal clad laminate and wiring board.

[1] A curable polymer containing one or more type(s) of structural units (UX) represented by the following formula and which is for production of a prepreg, a metal clad laminate or a wiring board:

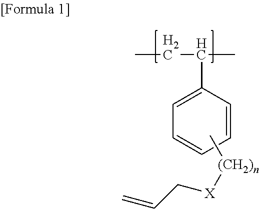

in which X is a single bond or an oxygen atom; the benzene ring optionally has a substituent other than the substituent in the above formula; and n is an integer of 0 or more.
[2] The curable polymer according to [1], in which the curable polymer is a copolymer containing one or more type(s) of structural units (UX) and one or more type(s) of monovinyl aromatic compound-derived structural units (UY).
[3] The curable polymer according to [1] or [2], in which a content of the one or more type(s) of structural units (UX) based on a total amount of 100% by mol of all the structural units is 1 to 90% by mol.
[4] The curable polymer according to [1] or [2], in which X is a single bond.
[5] The curable polymer according to [1] or [2], in which n is 1 to 18.
[6] A curable composition including the curable polymer according to [1] or [2]. [7] The curable composition according to [6], further including other curable compound having one or more type(s) of polymerizable functional groups.
[8] A prepreg including a fibrous substrate, and a semi-cured product or cured product of the curable composition according to [6].
[9] A multilayer body including a substrate, and a curable composition layer consisting of the curable composition according to [6].
[10] A multilayer body including a substrate, and a (semi-) cured product-containing layer including a semi-cured product or cured product of the curable composition according to [6].
[11] A metal clad laminate including an insulating layer containing a cured product of the curable composition according to [6], and metal foil.
[12] A wiring board including an insulating layer including a cured product of the curable composition according to [6], and wiring.

The present disclosure can provide a curable polymer capable of producing a resin with sufficiently low dielectric dissipation factor (D_{f}) under high-frequency conditions and sufficiently high glass transition temperature (Tg), and a curable composition containing the same.

The above and other objects, features and advantages of the present disclosure will become more fully understood from the detailed description given hereinbelow and the accompanying drawings.

### BRIEF DESCRIPTION OF DRAWINGS

FIG. 1 is a schematic cross-sectional view of a metal clad laminate according to a first embodiment of the disclosure;

FIG. 2 is a schematic cross-sectional view of a metal clad laminate according to a second embodiment of the disclosure; and

FIG. 3 is a schematic cross-sectional view of a wiring board according to an embodiment of the disclosure.

### DESCRIPTION OF EMBODIMENTS

As used herein, (semi-) curing is a general term for semi-curing and curing.

As used herein the term “wiring board” includes a multilayer wiring board unless otherwise specified.

As used herein, the “polymer” encompasses a homopolymer and a copolymer, unless otherwise specified.

As used herein, the “alkyl group having 3 or more carbon atoms” may be linear or branched, unless otherwise specified.

As used herein, a compound whose isomers are present encompasses all such isomers, unless otherwise specified.

As used herein, the “weight average molecular weight (Mw)” means the weight average molecular weight in terms of standard polystyrene obtained by a gel permeation chromatography (GPC) method, and the “number average molecular weight (Mn)” means the number average molecular weight in terms of polystyrene obtained by a gel permeation chromatography (GPC) method, unless otherwise specifies.

As used herein, Me represents a methyl group, Et represents an ethyl group, ^{t}Bu represents a t-butyl group, and Ph represents a phenyl group in any chemical formula.

As used herein, the term “high-frequency region” is defined as a region with a frequency of 1 GHz or higher.

As used herein, the term “to” indicating a numerical range is used in a sense that numerical values described before and after “to” are included as a lower limit value and an upper limit value.

Hereinafter, embodiments of the present disclosure are described.

### [Curable Polymer]

The curable polymer of the present disclosure is a homopolymer or copolymer containing a structural unit (UX) represented by the following formula, and is for production of a prepreg, a metal clad laminate or a wiring board.

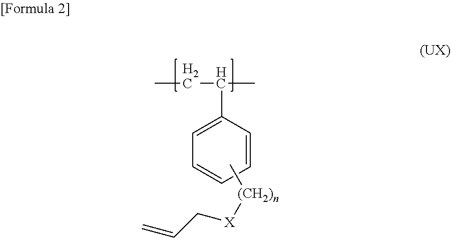

The above formula is also referred to as formula (UX).

In the formula (UX), X is a single bond or an oxygen atom, and is preferably a single bond.

n is an integer of 0 or more. The benzene ring optionally has a substituent other than a substituent (SX) represented by the following formula.

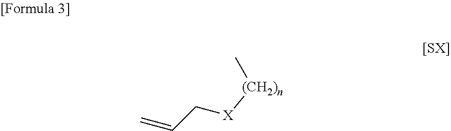

When the curable polymer of the present disclosure is a copolymer, the curable polymer of the present disclosure may be a copolymer containing a plurality of structural units (UX), or may be a copolymer containing one or more type(s) of structural units (UX) and one or more type(s) of other structural units other than the structural units (UX).

Such other structural unit is preferably a monovinyl aromatic compound-derived structural unit (UY) from the viewpoint of an enhancement in glass transition temperature (Tg) of a cured product of the curable polymer of the present disclosure.

The monovinyl aromatic compound is a compound containing a structure in which one polymerizable vinyl group is linked to an aromatic ring. The polymerizable vinyl group may be a substituent on the aromatic ring, or a vinyl group contained in a cyclopentadiene ring fused to the aromatic ring.

Examples include styrene and vinylnaphthalene; alkyl-substituted styrenes such as methylstyrene, ethylstyrene, and t-butylstyrene; alkyl-substituted vinylnaphthalenes; other alkyl-substituted aromatic vinyl compounds; dialkyl-substituted styrenes such as dimethylstyrene; other dialkyl-substituted aromatic vinyl compounds; α-alkyl-substituted styrenes such as α-methylstyrene; other α-alkyl-substituted aromatic vinyl compounds; β-alkyl-substituted styrenes such as β-methylstyrene; other β-alkyl-substituted aromatic vinyl compounds; indene, acenaphthylene; and their derivatives such as substituted bodies and modified bodies.

When the monovinyl aromatic compound has structural isomers, any of ortho-, meta-, and para-isomers may be used.

Examples of the structural units (UY) include structural units represented by the following formulas (UY-1) to (UY-5).

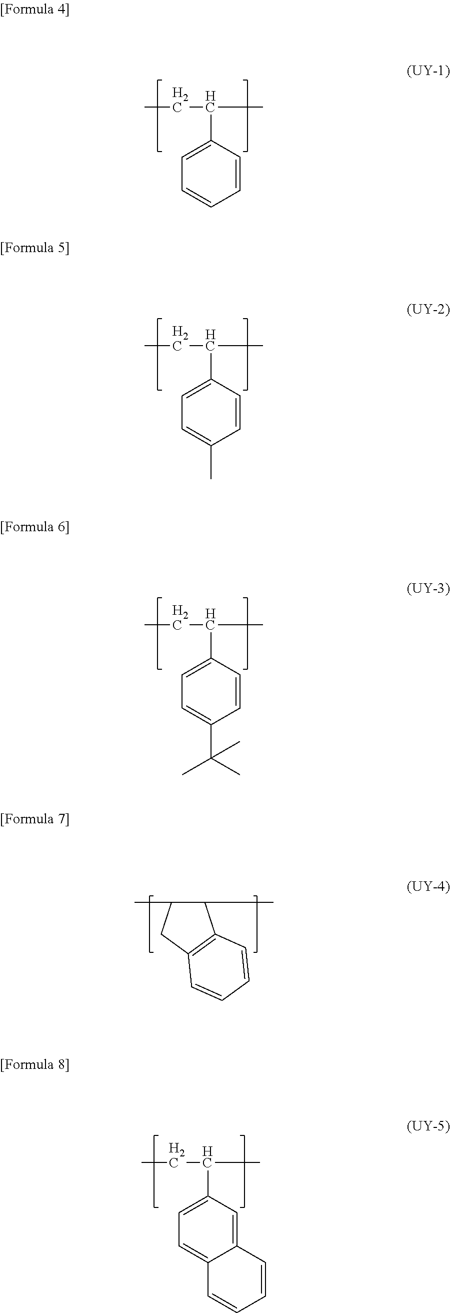

The present inventors have investigated and found that the dielectric dissipation factor (D_{f}) under high-frequency conditions of the (semi-) cured product of the curable composition can be sufficiently low by using the curable polymer of the present disclosure.

The content of the one or more type(s) of structural units (UX) based on a total amount of 100% by mol of all the structural units in the curable polymer of the present disclosure is not particularly limited. The present inventors have investigated and found that the higher the content of the structural units (UX), the relatively higher the dielectric dissipation factor (D_{f}) under high-frequency conditions of the (semi-) cured product of the curable composition tends to be, in comparison when conditions other than the content of the structural units (UX) are uniform.

A copolymer containing one or more type(s) of structural units (UX) and one or more type(s) of other structural units other than the structural units (UX) (preferably, one or more type(s) of monovinyl aromatic compound-derived structural units (UY)) as structural units, rather than a homopolymer or copolymer containing only one or more type(s) of structural units (UX), tends to be able to effectively reduce the dielectric dissipation factor (D_{f}) under high-frequency conditions of the (semi-) cured product of the curable composition.

The curable polymer of the present disclosure is preferably a copolymer containing one or more type(s) of structural units (UX) and one or more type(s) of monovinyl aromatic compound-derived structural units (UY) since the dielectric dissipation factor (D_{f}) under high-frequency conditions of the (semi-) cured product of the curable composition can be effectively reduced.

The content of the one or more type(s) of structural units (UX) based on a total amount of 100% by mol of all the structural units in the curable polymer of the present disclosure is preferably 1 to 90% by mol, more preferably 1 to 50% by mol, particularly preferably 5 to 50% by mol, and most preferably 5 to 25% by mol since the dielectric dissipation factor (D_{f}) under high-frequency conditions of the (semi-) cured product of the curable composition can be effectively reduced.

In the structural unit (UX), the substituent (SX) may be attached to the benzene ring at any of ortho-, meta- and para-positions, and is preferably at para-position from the viewpoint the ease of synthesis of a monomer, the ease of synthesis of the curable polymer of the present disclosure, and the like.

The benzene ring in the structural unit (UX) may have a further substituent other than the substituent (SX). Examples of such a further substituent that may be contained in the benzene ring include an alkyl group having 1 to 18 carbon atoms and an aryl group. From the viewpoint of availability of raw materials, preferred are a methyl group, an ethyl group, a propyl group, a butyl group, a hexyl group, an octyl group, a phenyl group and a tolyl group. The benzene ring in the structural unit (UX) preferably has no substituent other than the substituent (SX).

In the structural unit (UX), n is an integer of 0 or more, preferably 1 to 18, more preferably 1 to 12, and particularly preferably 1 to 8.

The curable polymer of the present disclosure may be either a thermosetting polymer or an active energy-ray curable polymer. The active energy ray-curable polymer is a polymer cured by irradiation with an active energy ray, such as an ultraviolet ray and an electron beam, and is preferably a thermosetting polymer for applications such as a metal clad laminate and a wiring board.

The curable polymer of the present disclosure, including one or more type(s) of structural units (UX), can be produced by homopolymerization or copolymerization of one or more type(s) of monomers (MX) represented by the following formula, or by copolymerization of one or more type(s) of monomers (MX) represented by the following formula and one or more type(s) of other monomers other than the monomers (MX) (preferably one or more type(s) of other monomers containing one or more type(s) of monovinyl aromatic compounds) copolymerizable therewith.

In other words, the curable polymer of the present disclosure is a homopolymer or copolymer of the one or more type(s) of monomers (MX), or a copolymer of the one or more type(s) of monomers (MX) and one or more type(s) of other monomers other than the monomers (MX) (preferably one or more type(s) of other monomers containing one or more type(s) of monovinyl aromatic compounds) copolymerizable therewith.

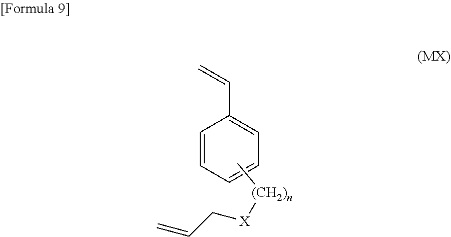

The above formula is also referred to as formula (MX).

In the formula (MX), X is a single bond or an oxygen atom, and is preferably a single bond. The benzene ring optionally has a substituent other than the substituent in the above formula. n is an integer of 0 or more. Preferred n is the same as that in the formula (UX).

The polymerization method is preferably chain polymerization or the like. Examples of the chain polymerization include cationic polymerization, anionic polymerization and radical polymerization, and cationic polymerization or the like is preferred.

The monomer (MX) can be synthesized by a known method with chloroalkylstyrene such as chloromethylstyrene (CMS), as a starting material. The monomer (MX) is preferably a CMS-modified body obtained with chloromethylstyrene (CMS) as a starting material.

Hereinafter, there is shown a first example of the reaction scheme of synthesis of the monomer (MX) with chloromethylstyrene (CMS) as a starting material and the reaction scheme of polymerization using the resulting monomer (MX). In this example, in the monomer (MX), X is a single bond, the substituent (SX) is attached to the benzene ring at para-position, and n is 1. This example shows copolymerization of the resulting monomer (MX) and styrene as the monovinyl aromatic compound.

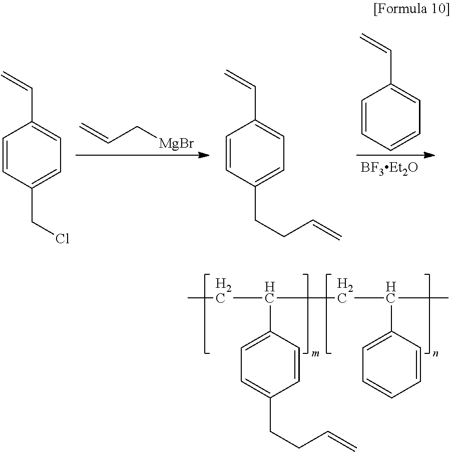

Hereinafter, there is shown a second example of the reaction scheme of synthesis of the monomer (MX) with chloromethylstyrene (CMS) as a starting material and the reaction scheme of polymerization using the resulting monomer (MX). In this example, in the monomer (MX), X is an oxygen atom, the substituent (SX) is attached to the benzene ring at para-position, and n is 1. This example shows copolymerization of the resulting monomer (MX) and styrene as the monovinyl aromatic compound.

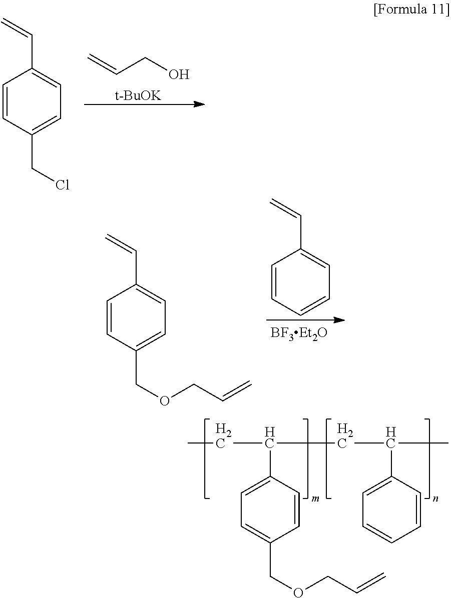

Examples of the curable polymer of the present disclosure include homopolymers represented by the following formulas (MC-11) and (MC-12).

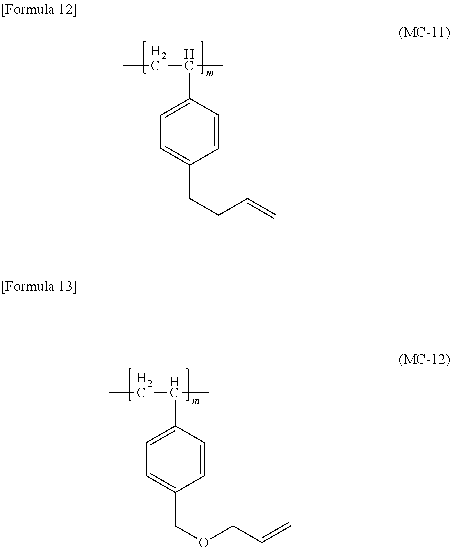

In the formulas (MC-11) and (MC-12), m represents the number of moles of the structural unit, and m>0 is satisfied. m is preferably 5 to 250, and more preferably 10 to 200. In these formulas, m is independent of m in the formulas (MX) and (SX).

Examples of the curable polymer of the present disclosure include copolymers represented by the following formulas (MC-21) to (MC-30). The arrangement of the structural units in such a copolymer may be any of alternate, block, and random arrangements.

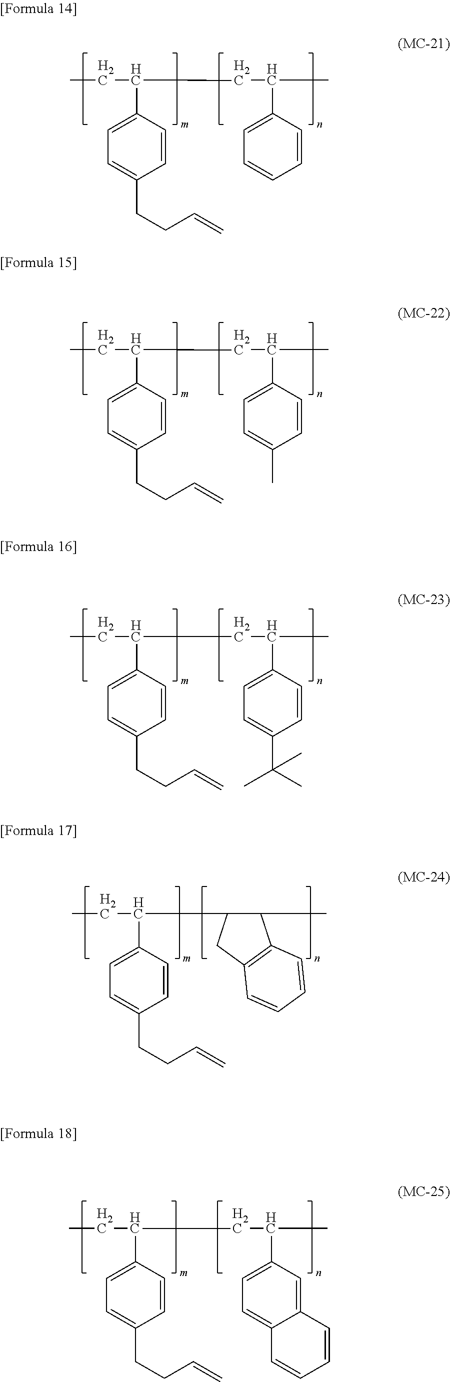

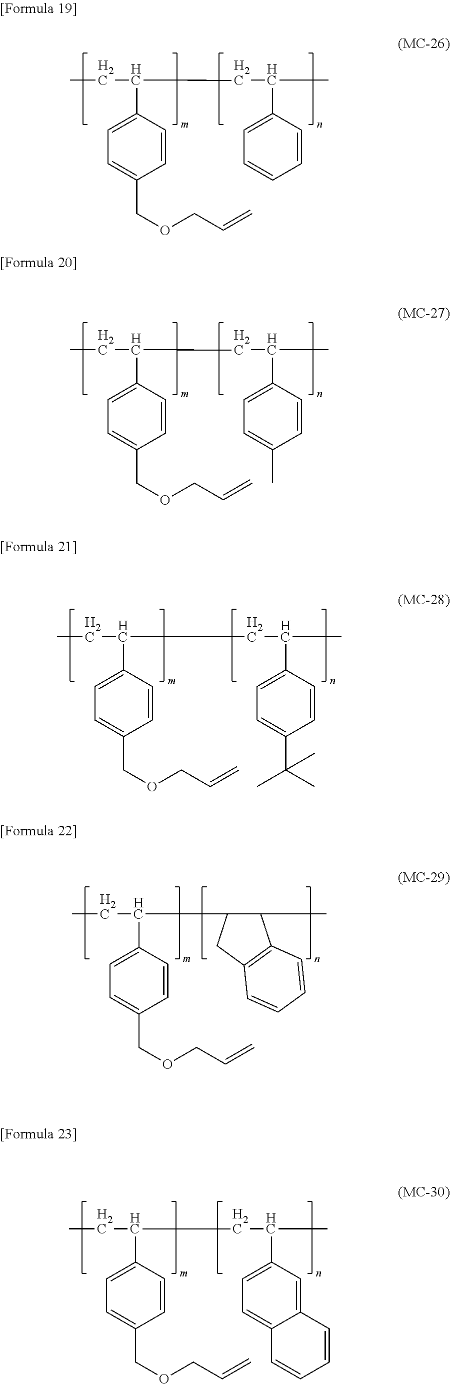

In the formulas (MC-21) to (MC-30), m and n represent the numbers of moles of the respective structural units, and m>0 and n>0 are satisfied. In these formulas, n is independent of n in the formulas (MX) and (SX).

When the total number of moles of m and n is 100% by mol, the mole fraction of m is preferably 1 to 90% by mol, and more preferably 5 to 50% by mol, and the mole fraction of n is preferably 99 to 10% by mol, and more preferably 95 to 50% by mol.

The molecular weight of the curable polymer of the present disclosure is not particularly limited. The number average molecular weight (Mn) is preferably 1000 to 20000, and more preferably 1000 to 5000. The weight average molecular weight (Mw) is preferably 2000 to 100000, and more preferably 3000 to 40000.

The curable polymer of the present disclosure can have a structure containing no polar atoms in a main chain, unlike a modified polyphenylene ether (modified PPE) oligomer having a polymerizable functional group at each of both ends, or the like.

The curable polymer of the present disclosure can have a structure containing no polar atoms or few polar atoms. The curable polymer of the present disclosure preferably has X being a single bond and contains no polar atoms.

A resin with effectively reduced dielectric dissipation factor (D_{f}) under high-frequency conditions can be obtained by using the curable polymer of the present disclosure, the polymer containing no polar atoms or few polar atoms.

### [Curable Composition]

The curable composition of the present disclosure includes one or more type(s) of the curable polymers of the present disclosure.

The curable composition of the present disclosure can include, if necessary, one or more type(s) of other curable compounds having one or more type(s) of polymerizable functional groups.

When the curable polymer of the present disclosure is singly cured and formed into a resin, such a resin, while depends on the molecular structure of the curable polymer, may be hard and brittle, and impracticable for a prepreg, a metal clad laminate or a wiring board. In this case, other appropriate curable compound can be used in combination to improve brittleness of the resulting resin to a practical level for a prepreg, a metal clad laminate or a wiring board.

The curable polymer of the present disclosure and other appropriate curable compound may be used in combination to enable the glass transition temperature (Tg) of the (semi-) cured product of the curable composition to be enhanced.

The curable composition of the present disclosure can further include, if necessary, one or more type(s) of optional components.

The curable composition of the present disclosure may be either a thermosetting composition or an active energy-ray curable composition, and is preferably a thermosetting composition for applications such as a metal clad laminate and a wiring board

Such other curable compound may be a monofunctional compound having one type of polymerizable functional groups, or may be a polyfunctional compound having two or more polymerizable functional groups.

Examples of the polymerizable functional group include a polymerizable carbon-carbon unsaturated bond-containing group, an epoxy group, an isocyanate group, a hydroxy group, a mercapto group, an amino group, a ureido group, a carboxy group, a sulfonic acid group, an acid chloride group, and a chlorine atom.

Examples of the polymerizable carbon-carbon unsaturated bond-containing group include a vinyl group, an allyl group, a dienyl group, a (meth)acryloyloxy group, and a (meth)acrylamino group.

Examples of such other curable compound include curable compounds which, when singly cured, are formed into resins such as a polyphenylene ether resin (PPE), a bismaleimide resin, an epoxy resin, a fluorine resin, a polyimide resin, an olefin resin, a polyester resin, a polystyrene resin, a hydrocarbon elastomer, a benzoxazine resin, an active ester resin, a cyanate ester resin, a butadiene resin, a hydrogenated or non-hydrogenated styrene-butadiene resin, a vinyl resin, a cycloolefin polymer, an aromatic polymer, and a divinyl aromatic polymer.

Examples of forms of such other curable compound include a monomer, an oligomer and a prepolymer.

Such other curable compound is represented by, for example, the following formula (PPE-o), and examples include a modified polyphenylene ether (modified PPE) oligomer having a polymerizable functional group at each of both ends.

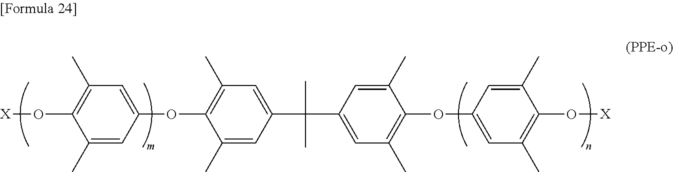

m and n in the formula (PPE-o) are independent of m and n in the formulas (MX), (SX), (MC-11), (MC-12), and (MC-21) to (MC-30).

X at both ends of the formula (PPE-o) each independently represents a group represented by the following formula (x1) or formula (x2), where “*” represents a bond to an oxygen atom.

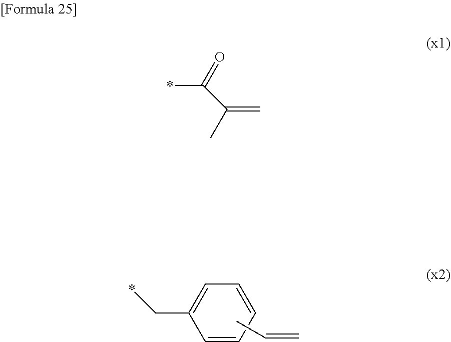

In the formula (PPE-o), m is preferably 1 to 20, more preferably 3 to 15, and n is preferably 1 to 20, more preferably 3 to 15.

The number average molecular weight (Mn) of the modified polyphenylene ether (modified PPE) oligomer is not particularly limited, and is preferably 1000 to 5000, and more preferably 1000 to 4000.

Also in a case where the curable polymer of the present disclosure and other curable compound containing polar atoms in a main chain, for example, the modified polyphenylene ether (modified PPE) oligomer, are used in combination in the curable compound, the amount of polar atoms contained in the (semi-) cured product of the curable composition can be reduced as compared with a case where only a curable compound containing many polar atoms, such as a modified PPE oligomer, is used in the curable compound. As a result, the dielectric dissipation factor (D_{f}) of the (semi-) cured product of the curable composition can be effectively reduced.

The content of one or more type(s) of the curable polymers of the present disclosure based on a total amount of 100 parts by mass of one or more type(s) of the curable polymers of the present disclosure and one or more type(s) of other curable compounds, in the curable composition of the present disclosure, is preferably higher, and is preferably 20 to 100 parts by mass, more preferably 30 to 100 parts by mass, particularly preferably 50 to 100 parts by mass, and most preferably 70 to 100 parts by mass since the dielectric dissipation factor (D_{f}) under high-frequency conditions of the (semi-) cured product of the curable composition can be effectively reduced.

The curable composition preferably includes one or more type(s) of polymerization initiators. As the polymerization initiators, organic peroxides, azo-based compounds, other known polymerization initiators and combinations thereof can be used. Specific examples thereof include dicumyl peroxide, benzoyl peroxide, cumene hydroperoxide, 2,5-dimethylhexane-2,5-dihydro peroxide, 2,5-dimethyl-2,5-di(t-butylperoxy)hexyne-3, di-t-butyl peroxide, t-butylcumyl peroxide, α,α′-di(t-butylperoxy)diisopropylbenzene, 2,5-dimethyl-2,5-di(t-butylperoxy)hexane, di-t-butyl peroxyisophthalate, t-butyl peroxybenzoate, 2,2-bis(t-butylperoxy)butane, 2,2-bis(t-butylperoxy)octane, 2,5-dimethyl-2,5-di(benzoylperoxy)hexane, di(trimethylsilyl)peroxide, trimethylsilyl triphenylsilyl peroxide and azobisisobutyronitrile.

The curable composition can optionally contain one or more type(s) of additives, such as an inorganic filler (also referred to as a filler), a compatibilizers and a flame retardant, if necessary.

Examples of the inorganic filler include metal oxides such as silica (e.g. spherical silica), alumina, titanium oxide and mica; metal hydroxides such as aluminum hydroxide and magnesium hydroxide; talc; aluminum borate; barium sulfate; and calcium carbonate. One or more type(s) of these can be used. Among them, silica, mica, talc and the like are preferred, and spherical silica is more preferred, from the viewpoint of low thermal expansion.

The inorganic filler may be surface-treated with a silane coupling agent of an epoxy silane type, a vinyl silane type, a methacrylic silane type or an amino silane type. The timing of the surface treatment with the silane coupling agent is not particularly limited. The inorganic filler surface-treated with the silane coupling agent may be prepared in advance, or the silane coupling agent may be added by an integral blend method during the preparation of the curable composition.

Examples of the flame retardant include a halogen flame retardant and a phosphorus flame retardant. One or more type(s) of these can be used. Examples of the halogen flame retardant include brominated flame retardants such as pentabromodiphenyl ether, octabromodiphenyl ether, decabromodiphenyl ether, tetrabromobisphenol A and hexabromocyclododecane; and chlorinated flame retardants such as chlorinated paraffin. Examples of the phosphorus flame retardant include phosphates such as a fused phosphate and a cyclic phosphate; phosphazene compounds such as a cyclic phosphazene compound; phosphinate flame retardants such as an aluminum dialkylphosphinate salt; melamine flame retardants such as melamine phosphate and melamine polyphosphate; and phosphine oxide compounds having a diphenylphosphine oxide group.

The curable composition may optionally contain one or more type(s) of organic solvents, if necessary. Examples of the organic solvents include, but are not particularly limited to, ketones such as methyl ethyl ketone; ethers such as dibutyl ether; esters such as ethyl acetate; amides such as dimethylformamide; aromatic hydrocarbons such as benzene, toluene and xylene; and chlorinated hydrocarbons such as trichloroethylene.

In the curable composition, the formulation composition and solid concentration can be appropriately designed.

The formulation composition of the curable composition can be designed so that the resulting (semi-) cured product is not embrittled and properties of the resulting (semi-) cured product, for example, the dielectric dissipation factor (Df) and the glass transition temperature (Tg) are suitable.

In applications such as a prepreg, the solid concentration of the curable composition can be designed so that the fibrous substrate is easily impregnated with the curable composition, and is preferably 50 to 90% by mass.

### [Prepreg]

The prepreg of the present disclosure include a fibrous substrate and a (semi-) cured product of the curable composition of the present disclosure.

The prepreg can be produced by impregnating a fibrous substrate with the curable composition and (semi-) curing, for example, by thermal curing.

The (semi-) cured product can include a singly cured product of one of the curable polymer of the present disclosure, a reaction product of a plurality of the curable polymers of the present disclosure, or a reaction product of one or more type(s) of the curable polymers of the present disclosure and one or more type(s) of other curable compounds.

The (semi-) cured product can include, if necessary, an additive such as an inorganic filler (filler).

Examples of the material of the fibrous substrate include, but are not particularly limited to, inorganic fibers such as a glass fiber, a silica fiber and a carbon fiber; organic fibers such as an aramid fiber and a polyester fiber; and combinations thereof. In applications such as a metal clad laminate and a wiring board, the glass fiber or the like is preferred. Examples of forms of the glass fibrous substrate include glass cloth, glass paper and glass mat.

Curing conditions for the curable composition can be set according to the composition of the curable composition, and semi-curing conditions (conditions under which complete curing does not occur) are preferred.

Thermal curing by heating at, for example, 80 to 180° C. for 1 to 10 minutes is preferred.

In applications such as a metal clad laminate and a wiring board, it is preferable to adjust the composition of the curable composition and curing conditions so that the resin content in the resulting prepreg is in the range of 40 to 80% by mass.

### [Multilayer Body]

The first multilayer body of the present disclosure includes a substrate and a curable composition layer consisting of the curable composition of the present disclosure described above.

The second multilayer body of the present disclosure includes a substrate and a (semi-) cured product-containing layer containing the (semi-) cured product of the curable composition of the present disclosure described above.

In the multilayer bodies of the present disclosure, examples of the substrate include, but are not particularly limited to, a resin film, a metal foil and a combination thereof.

The (semi-) cured product-containing layer may be a layer containing a fibrous substrate and a (semi-) cured product of the curable composition of the present disclosure.

The resin film is not particularly limited, and a known resin film is available. Examples of constituent resins of the resin film include polyimide, polyethylene terephthalate (PET), polyethylene naphthalate, cycloolefin polymer and polyether sulfide.

Due to its low electrical resistance, the metal foil is preferably copper foil, silver foil, gold foil, aluminum foil and combinations thereof, and more preferably copper foil and the like.

### [Metal Clad Laminate]

The metal clad laminate of the present disclosure includes an insulating layer containing a cured product of the curable composition of the present disclosure and metal foil.

The insulating layer may be a layer containing a fibrous substrate and a cured product of the curable composition of the present disclosure.

Due to its low electrical resistance, the metal foil is preferably copper foil, silver foil, gold foil, aluminum foil and combinations thereof, and more preferably copper foil and the like. The metal foil may have a metal plating layer on its surface. The metal foil may be a metal foil with a carrier including an ultra-thin metal foil and a carrier metal foil supporting the ultrathin metal foil. The metal foil may have at least one surface subjected to surface treatments such as anticorrosion, silanization, roughening and barrier-forming treatment.

The thickness of the metal foil is not particularly limited but is preferably 0.1 to 100 μm, more preferably 0.2 to 50 μm, and particularly preferably 1.0 to 40 μm since it is suitable for the formation of a conductive pattern (also referred to as a circuit pattern) such as wiring.

The metal clad laminate may be a single-sided metal clad laminate with metal foil on one side or a double-sided metal clad laminate with metal foil on both sides and is preferably a double-sided metal clad laminate.

The single-sided metal clad laminate can be produced by stacking one or more of the above prepreg(s) and metal foil and heating and pressing the resulting first temporary multilayer body.

The double-sided metal clad laminate can be produced by sandwiching one or more of the above prepreg(s) between a pair of metal foils and heating and pressing the resulting first temporary multilayer body.

A metal clad laminate that uses copper foil as the metal foil is referred to as a copper clad laminate (CCL).

The insulating layer preferably consists of a heat-pressed product of the prepreg, which contains a fibrous substrate and a resin and may optionally contain one or more types of additives such as an inorganic fillers and a flame retardant, if necessary. The heat-pressed product of the prepreg is also referred to as a composite substrate.

The heating and pressing conditions of the first temporary multilayer body are not particularly limited, and for example, a temperature of 170 to 250° C., a pressure of 0.3 MPa to 30 MPa, and a time of 3 to 240 minutes are preferred.

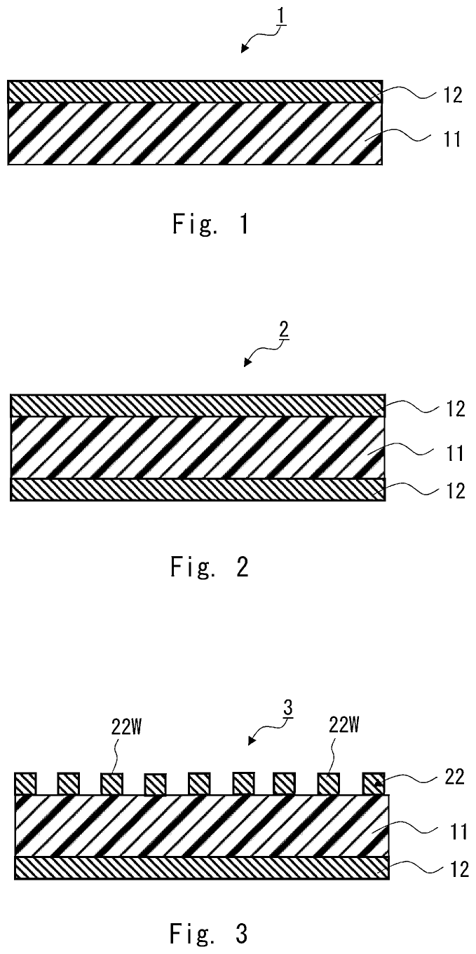

FIGS. 1 and 2 show schematic cross-sectional views of metal clad laminates according to the embodiments of the present disclosure.

The metal clad laminate 1 shown in FIG. 1 is a single-sided metal clad laminate (multilayer body) in which metal foil (metal layer) 12 is laminated on one side of a composite substrate (cured product-containing layer) 11, which consists of a heat-pressed product of the prepreg and contains a cured product of the curable composition of the present disclosure.

The metal clad laminate 2 shown in FIG. 2 is a double-sided metal clad laminate in which metal foil (metal layer) 12 is laminated on both sides of a composite substrate (cured product-containing layer) 11, which consists of a heat-pressed product of the prepreg and contains a cured product of the curable composition of the present disclosure.

The metal clad laminates 1 and 2 may have layers other than those described above.

The metal clad laminates 1 and 2 can have an adhesive layer between the composite substrate (cured product-containing layer) 11 and the metal foil (metal layer) 12 in order to enhance the adhesion therebetween. As the material of the adhesive layer, a known material is available. Examples thereof include an epoxy resin, a cyanate ester resin, an acrylic resin, a polyimide resin, a maleimide resin, an adhesive fluororesin and combinations thereof. Examples of commercially available adhesive fluororesins include “Fluon LM-ETFE LH-8000,” “AH-5000,” “AH-2000” and “EA-2000,” all of which are manufactured by AGC Inc.

The thickness of the composite substrate can be designed as appropriate according to the application. From the viewpoint of preventing disconnection of the wiring board, the thickness is preferably 50 μm or more, more preferably 70 μm or more, and particularly preferably 100 μm or more. From the viewpoint of flexibility, miniaturization, and weight reduction of the wiring board, the thickness is preferably 300 μm or less, more preferably 250 μm or less, and particularly preferably 200 μm or less.

### [Wiring Board]

The wiring board of the present disclosure includes an insulating layer containing a cured product of the curable composition of the present disclosure and wiring.

The wiring board can be manufactured by forming a conductive pattern (circuit pattern) such as wiring using the metal foil on the outermost surface of the metal clad laminate of the present disclosure described above. Examples of methods of forming a conductive pattern such as wiring include a subtractive method, in which metal foil is etched to form wiring or the like, and modified semi additive process (MSAP), in which metal foil is plated to form wiring on the metal foil.

FIG. 3 shows a schematic cross-sectional view of a wiring board according to an embodiment of the present disclosure. In the wiring board 3 shown in FIG. 3, a conductive pattern (circuit pattern) 22 such as wiring 22W is formed by using the metal foil 12 on at least one outermost surface of the metal clad laminate 2 of the second embodiment shown in FIG. 2.

The wiring board 3 is composed of a heat-pressed product of the prepreg, in which the conductive pattern (circuit pattern) 22 such as wiring 22W is formed on at least one surface of the composite substrate (cured product-containing layer, insulating layer) 11 containing a cured product of the curable composition of the present disclosure.

One or more prepreg(s) may be further stacked on the resulting wiring board, which is sandwiched between a pair of metal foils, and the obtained second temporary multilayer body may be heated and pressed to form a conductive pattern of wiring or the like using the outermost metal foil, thereby manufacturing a multilayer wiring board (also referred to as a multilayer printed wiring board). The outermost metal foil may be arranged only on one side of the second temporary multilayer body.

The wiring board of the present disclosure is suitable for use in a high-frequency region (a region with a frequency of 1 GHz or higher).

In recent applications such as portable electronic devices, signals have become increasingly high-frequency as higher speeds and larger capacities of communication have been achieved. The wiring board used in the such applications is required to have reduced transmission loss in the high-frequency region. For this reason, the resin contained in the composite substrate for the wiring board used in the above applications is required to have reduced dielectric loss in the high-frequency region. The dielectric dissipation factor (D_{f}) generally depends on frequency. Given the same material, the higher the frequency, the larger the dielectric dissipation factor (D_{f}) tends to be. The resin contained in the composite substrate preferably has a low dielectric dissipation factor (D_{f}) under high-frequency condition.

The wiring board may be used in a relatively high-temperature environment. Even in this case, in order to ensure the reliability of the wiring board, the resin contained in the prepreg and the composite substrate preferably has a sufficiently high glass transition temperature (Tg).

If there is a big difference in coefficient of thermal expansion (CTE) between the prepreg or composite substrate and the metal foil, misalignment or delamination of the metal foil may occur when heating and pressing the first temporary multilayer body containing the prepreg and the metal foil or the second temporary multilayer body containing the composite substrate, the prepreg and the metal foil. Preferably, the difference in the coefficient of thermal expansion (CTE) between the prepreg or composite substrate and the metal foil is small. Since the resin generally has a larger coefficient of thermal expansion (CTE) than the metal foil, a lower coefficient of thermal expansion (CTE) for the prepreg and composite substrate is preferred.

The present inventors have investigated and found that the dielectric dissipation factor (D_{f}) under high-frequency conditions of the (semi-) cured product of the curable composition can be sufficiently low by using the curable polymer of the present disclosure, the polymer containing no polar atoms or few polar atoms.

It was also found that the (semi-) cured product of the curable composition containing the curable polymer of the present disclosure had a sufficiently high glass transition temperature (Tg).

It was also found that the (semi-) cured product of the curable composition containing the curable polymer of the present disclosure had a sufficiently low coefficient of thermal expansion (CTE).

In addition, it was found that the (semi-) cured product of the curable composition containing the curable polymer of the present disclosure also had a practically good adhesion to metals such as copper foil.

By using the curable polymer of the present disclosure, it is possible to obtain a resin with sufficiently low dielectric dissipation factor (D_{f}) under high-frequency conditions and sufficiently high glass transition temperature (Tg). This (semi-) cured product is suitable for a composite substrate, an insulating layers and the like, which are suitable for wiring boards used in the high-frequency region.

The dielectric dissipation factor (D_{f}) of the (semi-) cured product of the curable composition of the present disclosure and the composite substrate containing the same under high-frequency conditions is preferably within, for example, the following ranges.

The dielectric dissipation factor (D_{f}) at a frequency of 10 GHz is preferably smaller, preferably 0.010 or less, more preferably 0.005 or less, further preferably 0.003 or less, particularly preferably 0.002 or less, and most preferably less than 0.002.

The dielectric dissipation factor (D_{f}) at a frequency of 10 GHz can be 0.0019 or less, 0.0017 or less, or 0.0014 or less.

The lower limit of the dielectric dissipation factor (D_{f}) at a frequency of 10 GHz is not particularly limited, and is, for example, 0.0001.

The glass transition temperature (Tg) of the (semi-) cured product of the curable composition of the present disclosure is preferably 150° C. or higher, more preferably 180° C. or higher, and particularly preferably 200° C. or higher. The upper limit is not particularly limited, for example, 300° C.

The coefficient of thermal expansion (CTE) of the (semi-) cured product of the curable composition of the present disclosure and the composite substrate containing the same is preferably within, for example, the following ranges.

The coefficient of thermal expansion (CTE) is preferably smaller, preferably 70 ppm/° C. or less, more preferably 60 ppm/° C. or less, particularly preferably 50 ppm/° C. or less, and most preferably 40 ppm/° C. or less. The lower limit thereof is not particularly limited, for example, 1 ppm/° C.

The dielectric dissipation factor (D_{f}) and glass transition temperature (Tg) can be measured by methods described in the Examples section below.

The coefficient of thermal expansion (CTE) can be measured with a commercially available thermomechanical analyzer, by a known method.

As described above, the present disclosure can provide a curable polymer capable of producing a resin with sufficiently low dielectric dissipation factor (D_{f}) under high-frequency conditions and sufficiently high glass transition temperature (Tg), and a curable composition containing the same.

Although the curable polymer of the present disclosure and the curable composition including the same are suitable for applications such as a prepreg, a metal clad laminate and a wiring board, they can be used in any application.

### Application

The curable polymer of the present disclosure and the curable composition including the same are suitable for applications such as a prepreg, a metal clad laminate and a wiring board.

The curable composition containing the curable polymer of the present disclosure is suitable for use in a curable composition for applications such as a prepreg, a metal clad laminate and a wiring board.

The metal clad laminate of the present disclosure is suitable for use as a wiring board, for example, for various electrical and electronic devices.

The wiring board of the present disclosure is suitable for use, for example, in portable electronic devices such as a mobile phone, a smartphone, a personal digital assistant and a laptop computer; antennas for a mobile phone base station and a vehicle; electronic devices such as a server, a router and a backplane; wireless infrastructures; radars for collision avoidance and the like; and various sensors (e.g., automotive sensors such as engine management sensors).

The wiring board of the present disclosure is particularly suitable for applications in which communication is performed using a high-frequency signal and various applications in which a reduction in transmission loss is required in a high-frequency region.

### EXAMPLES

Hereinafter, the present disclosure is described in detail with reference to examples, but the present disclosure is not limited thereto. Examples 11 to 13, 21, 31, 41, 51, 101 to 107 and 301 are Examples, while Example 201 is Comparative Example. Unless otherwise specified, room temperature is around 25° C.

### [Commercially Available Reagent]

In the Examples section, commercially available catalysts and reagents were used as received for reactions unless otherwise specified. The solvents used were dehydrated and deoxygenated commercial solvents.

### [Evaluation Item and Evaluation Method of Curable Polymer]

### (Structure of Monomer)

The structure of the synthesized monomer was identified using a nuclear magnetic resonance device (“AVANCE NEO400” manufactured by Bruker) by carrying out ¹H-NMR measurement.

### (Number Average Molecular Weight (Mn) and Weight Average Molecular Weight (Mw))

The number average molecular weight (Mn) and weight average molecular weight (Mw) of the synthesized curable polymer were determined by a gel permeation chromatography (GPC) method. The GPC device used was “HLC-8320GPC” manufactured by Tosoh Corporation, provided with a differential refractive index detector (RI detector). The eluent used was tetrahydrofuran. The column used was one in which four columns of “TSKgel SuperHZ2000”, “TSKgel SuperHZ2500”, “TSKgel SuperHZ3000” and “TSKgel SuperHZ4000” (all were manufactured by Tosoh Corporation) were connected in series. A sample solution was prepared by dissolving 20 mg of a resin in 2 mL of tetrahydrofuran. Injected was 10 μl of the sample solution, and chromatogram was measured. GPC measurement was carried out by using 10 standard polystyrenes having a molecular weight within a range of 400 to 5000000, and the calibration curve representing the relationship between the retention time and the molecular weight was created. The Mn and Mw of the curable polymer were determined based on the calibration curve.

### [Evaluation Item and Evaluation Method of Cured Film Product]

(Dielectric Constant (Dₖ) and Dielectric Dissipation Factor (D_{f}))

Dielectric constant (Dₖ) and dielectric dissipation factor (D_{f}) at 10 GHz of the evaluation sample (cured film product) were measured by the SPDR method using a vector network analyzer (“E8361C” manufactured by Agilent Technologies) at room temperature.

### (Glass Transition Temperature (Tg))

Dynamic mechanical analysis (DMA) was taken on the evaluation sample (cured film product) using a dynamic viscoelasticity measuring device (“DVA 200” manufactured by IT Keisoku Seigyo Co., Ltd.) to measure the glass transition temperature (Tg) (° C.) under conditions of a frequency of 10 Hz, a heating rate of 2° C./min, and a temperature range of 25° C. to 300° C.

### [Synthesis Example 1] Synthesis of p-(3-butenyl)styrene

Under a nitrogen atmosphere, a 500 mL four-necked flask was charged with a diethyl ether solution of allylmagnesium bromide (about 0.7 mol/L, 202 mL, 141 mmol). The flask was cooled to 0° C., and to the solution was added dropwise a solution of 4-(chloromethyl)styrene (15.5 mL, 98.7 mmol) in diethyl ether (35.1 mL) over 16 minutes, the flask was warmed to room temperature and the mixture was then stirred for 2.5 hours. The flask was cooled to 0° C., and to the reaction mixture was added a saturated aqueous ammonium chloride solution (140 mL) and the mixture was then stirred, followed by extraction to separate an organic phase. Diethyl ether (100 mL) was further added to the water phase, and extraction was performed twice to separate the organic phase. The organic phases obtained from these extractions were combined, the combined organic phases were dried over sodium sulfate and filtered, and the filtrate was concentrated under vacuum to give a crude product. The crude product was purified by silica gel column chromatography (mobile phase: n-hexane) to give 15.9 g of p-(3-butenyl)styrene as a colorless liquid (yield: 100%). The resulting compound was one monomer (MX) (X=single bond, n=1).

The reaction scheme and results of NMR analysis are as follows:

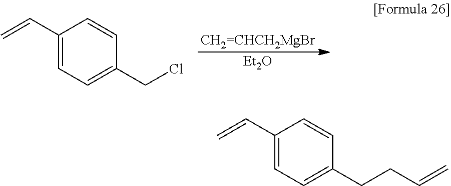

¹H-NMR (CDCl₃): δ (ppm) 7.33 (d, 2H, J=8.11 Hz, Ar—H), 7.14 (d, 2H, J=8.11 Hz, Ar—H), 6.69 (dd, 2H, J=10.85, 17.52 Hz), 5.90-5.80 (dm, 1H, J=10.13 Hz), 5.70 (dd, 1H, J=0.95, 17.52 Hz), 5.19 (dd, 1H, J=0.95, 10.85 Hz), 5.04 (ddt, 1H, J=1.67, 3.58, 17.17 Hz), 4.99 (dm, 1H, J=10.25 Hz), 2.70 (t, 2H, J=8.11 Hz), 2.36 (m, 2H).

### [Synthesis Example 2] Synthesis of allyl(4-vinylbenzyl)ether

Under a nitrogen atmosphere, a 300 mL four-necked flask was charged with potassium tert-butoxide (11.7 g, 103 mmol), tetrahydrofuran (167 mL), and allyl alcohol (7.00 mL, 103 mmol). To this suspension was added dropwise 4-(chloromethyl)styrene (18.1 mL, 115 mmol) at room temperature over 8 minutes, the flask was warmed to 50° C., and the mixture was then stirred for one hour. To the reaction mixture was added ion exchange water (140 mL) and the mixture was then stirred, followed by extraction to separate an organic phase. Ethyl acetate (140 mL) was further added to the water phase, followed by extraction to separate the organic phase. The organic phases obtained from these extractions were combined, the combined organic phases were dried over sodium sulfate and filtered, and the filtrate was concentrated under vacuum to give a crude product. The crude product was purified by silica gel column chromatography (mobile phase: n-hexane) to give 17.1 g of allyl(4-vinylbenzyl)ether as a pale yellow liquid (yield: 96%). The resulting compound was one monomer (MX) (X=oxygen atom, n=1).

The reaction scheme and results of NMR analysis are as follows:

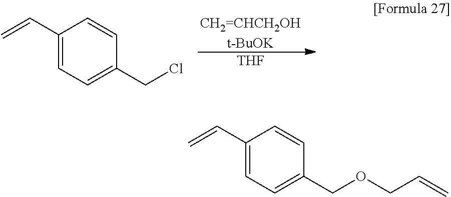

¹H-NMR (CDCl₃): δ (ppm) 7.39 (d, 2H, J=8.11 Hz, Ar—H), 7.30 (d, 2H, J=8.11 Hz, Ar—H), 6.71 (dd, 1H, J=6.68, 10.85 Hz), 5.95 (ddt, 1H, J=4.11, 9.50, 18.68 Hz), 5.74 (dd, 1H, J=0.83, 17.64 Hz), 5.30 (dq, 1H, J=1.67, 17.29 Hz), 5.23 (dd, 1H, J=0.83, 10.97 Hz), 5.22-5.19 (m, 1H), 4.51 (s, 2H), 4.02 (dt, 2H, J=1.43, 5.60 Hz).

### [Example 11] Synthesis of Copolymer (P11)

Under a nitrogen atmosphere, a 100-mL pressure-resistant reaction vessel was loaded with p-(3-butenyl)styrene (8.0 g, 50.6 mmol) obtained in Synthesis Example 1, styrene (12.0 g, 115.4 mmol), toluene (20 g, 21.7 mmol), and a boron trifluoride-diethyl ether complex (0.36 g, 2.6 mmol), and the mixture was then reacted at 50° C. for five hours. After completion of the reaction, a saturated aqueous sodium hydrogen carbonate solution was loaded to the polymerization solution to stop the reaction. This polymerization solution was added dropwise into a large amount of methanol to precipitate a polymerized product. The precipitated product was recovered, washed and dried to give 18.9 g of copolymer (P11) (yield: 94.7%).

### [Example 12] Synthesis of Copolymer (P12)

The same manner as in Example 11 was performed except that the amount of p-(3-butenyl)styrene was modified to 6.0 g, 38.0 mmol, and the amount of styrene was modified to 14.0 g, 134.6 mmol, to give 18.9 g of copolymer (P12) (yield: 94.4%).

### [Example 13] Synthesis of Copolymer (P13)

The same manner as in Example 11 was performed except that the amount of p-(3-butenyl)styrene was modified to 3.0 g, 19.0 mmol, and the amount of styrene was modified to 17.0 g, 163.5 mmol, to give 18.2 g of copolymer (P13) (yield: 90.8%).

The reaction scheme of Examples 11 to 13 is as follows:

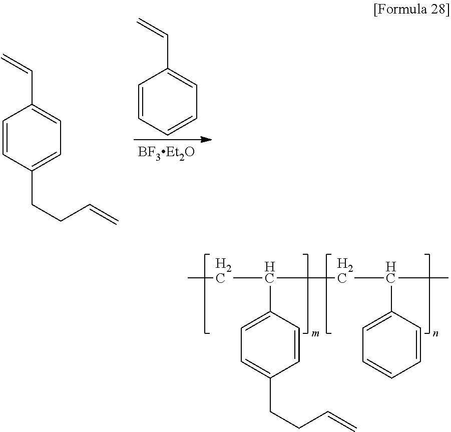

### [Example 21] Synthesis of Copolymer (P21)

Under a nitrogen atmosphere, a 100-mL pressure-resistant reaction vessel was loaded with p-(3-butenyl)styrene (4.0 g, 25.3 mmol), 4-tert-butylstyrene (16.0 g, 99.8 mmol), toluene (20 g, 21.7 mmol), and a boron trifluoride-diethyl ether complex (0.36 g, 2.6 mmol), and the mixture was then reacted at 50° C. for five hours. After completion of the reaction, a saturated aqueous sodium hydrogen carbonate solution was loaded to the polymerization solution to stop the reaction. This polymerization solution was added dropwise into a large amount of methanol to precipitate a polymerized product. The precipitated product was recovered, washed and dried to give 18.9 g of copolymer (P21) (yield: 94.7%).

The reaction scheme is as follows:

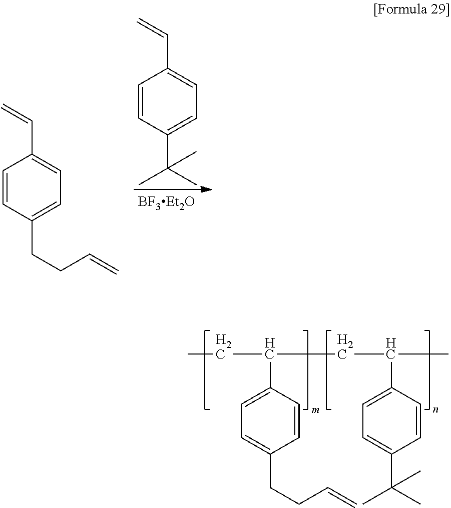

### [Example 31] Synthesis of Copolymer (P31)

Under a nitrogen atmosphere, a 100-mL pressure-resistant reaction vessel was loaded with p-(3-butenyl)styrene (3.0 g, 19.0 mmol), indene (8.4 g, 53.2 mmol), toluene (20 g, 21.7 mmol), and a boron trifluoride-diethyl ether complex (0.36 g, 2.6 mmol), and the mixture was then reacted at 50° C. for five hours. After completion of the reaction, a saturated aqueous sodium hydrogen carbonate solution was loaded to the polymerization solution to stop the reaction. This polymerization solution was added dropwise into a large amount of methanol to precipitate a polymerized product. The precipitated product was recovered, washed and dried to give 19.1 g of copolymer (P31) (yield: 95.3%).

The reaction scheme is as follows:

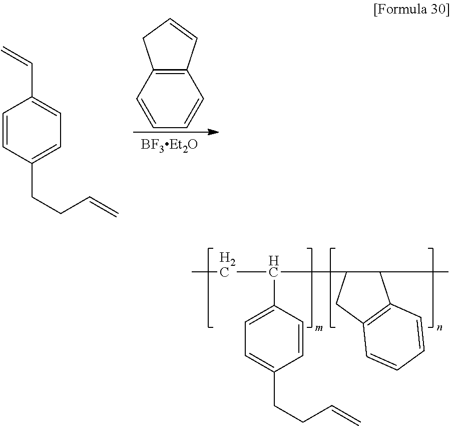

### [Example 41] Synthesis of Copolymer (P41)

Under a nitrogen atmosphere, a 100-mL pressure-resistant reaction vessel was loaded with p-(3-butenyl)styrene (4.2 g, 26.6 mmol), 2-vinylnaphthalene (15.8 g, 102.5 mmol), toluene (20 g, 21.7 mmol), and a boron trifluoride-diethyl ether complex (0.36 g, 2.6 mmol), and the mixture was then reacted at 50° C. for five hours. After completion of the reaction, a saturated aqueous sodium hydrogen carbonate solution was loaded to the polymerization solution to stop the reaction. This polymerization solution was added dropwise into a large amount of methanol to precipitate a polymerized product. The precipitated product was recovered, washed and dried to give 18.8 g of copolymer (P41) (yield: 93.9%).

The reaction scheme is as follows:

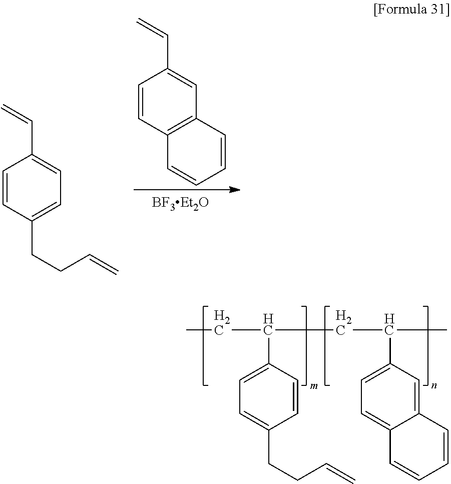

### [Example 51] Synthesis of Copolymer (P51)

Under a nitrogen atmosphere, a 100-mL pressure-resistant reaction vessel was loaded with allyl(4-vinylbenzyl)ether (3.2 g, 18.4 mmol) obtained in Synthesis Example 2, styrene (16.8 g, 161.5 mmol), toluene (20 g, 21.7 mmol), and a boron trifluoride-diethyl ether complex (0.36 g, 2.6 mmol), and the mixture was then reacted at 50° C. for five hours. After completion of the reaction, a saturated aqueous sodium hydrogen carbonate solution was loaded to the polymerization solution to stop the reaction. This polymerization solution was added dropwise into a large amount of methanol to precipitate a polymerized product. The precipitated product was recovered, washed and dried to give 19.9 g of copolymer (P41) (yield: 99.5%).

The reaction scheme is as follows:

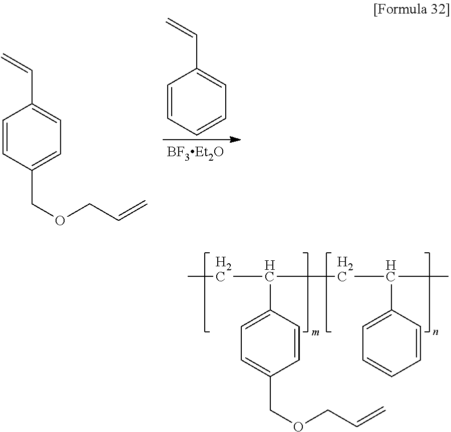

Table 1 shows the monomer composition and physical properties of each of the copolymers obtained in Examples 11 to 13, 21, 31, 41, and 51.

TABLE 1

| | | CMS-modified monomer | | Monovinyl aromatic compound | | | |
|---|---|---|---|---|---|---|---|
| | Curable | | Amount | | Amount | | |
| Example | polymer | Type | [% by mol] | Type | [% by mol] | Mn | Mw |
| 11 | P11 | p-(3-butenyl)styrene | 23 | Styrene | 77 | 2062 | 21933 |
| 12 | P12 | p-(3-butenyl)styrene | 17 | Styrene | 83 | 2195 | 16052 |
| 13 | P13 | p-(3-butenyl)styrene | 7 | Styrene | 93 | 1376 | 10048 |
| 21 | P21 | p-(3-butenyl)styrene | 20 | 4-tert-butylstyrene | 80 | 4938 | 35140 |
| 31 | P31 | p-(3-butenyl)styrene | 18 | Indene | 82 | 4797 | 18456 |
| 41 | P41 | p-(3-butenyl)styrene | 17 | Vinylnaphthalene | 83 | 1772 | 3553 |
| 51 | P51 | Allyl(4-vinylbenzyl)ether | 5 | Styrene | 95 | 2389 | 14222 |

### Example 101

Curable polymer (P11), the following modified polyphenylene ether (PPE) oligomer (SA9000), dicumyl peroxide (DCP) as a radical initiator and toluene were mixed in a mass ratio of 50:50:1:100 and stirred at room temperature to prepare a curable composition.

(SA9000) Bifunctional methacrylic modified PPE oligomer (“SA9000” manufactured by SABIC) represented by the following formula:

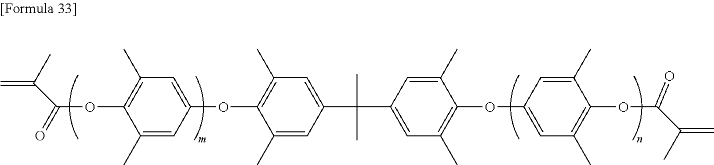

Next, the curable composition was applied onto a polyimide film with a thickness of 125 μm using an applicator (manufactured by YOSHIMITSU SEIKI) to form a 250 μm-thick coating film.

After heat-drying in an oven at 80° C. for 30 minutes in an air atmosphere, the coating film was heated under a nitrogen atmosphere at 200° C. for two hours to cause thermal curing of the coating film, thus obtaining a cured film product having a thickness of about 100 μm.

Table 2 shows the formulation composition excluding the solvent of the curable composition, and evaluation results of the resulting cured film product. The unit of the amount of formulation in the Table is “part(s) by mass”.

### Examples 102 to 107 and 201

Each curable composition was prepared and each cured film product was produced in the same manner as in Example 101 except that the types and amounts of formulation of one or more type(s) of curable polymers were modified. Table 2 shows the formulation composition excluding the solvent of the curable composition, and evaluation results of the resulting cured film product.

TABLE 2

| | | Example | Example | Example | Example | Example | Example | Example | Example |
|---|---|---|---|---|---|---|---|---|---|
| | | 101 | 102 | 103 | 104 | 105 | 106 | 107 | 201 |
| Curable | P11 | 50 | | | | | | | |
| composition | P12 | | 50 | | | | | | |
| | P13 | | | 50 | | | | | |
| | P21 | | | | 50 | | | | |
| | P31 | | | | | 50 | | | |
| | P41 | | | | | | 50 | | |
| | P51 | | | | | | | 50 | |
| | Modified PPE (SA9000) | 50 | 50 | 50 | 50 | 50 | 50 | 50 | 100 |
| | Polymerization initiator | 1 | 1 | 1 | 1 | 1 | 1 | 1 | 1 |
| | (DCP) | | | | | | | | |
| Cured film | Dk (10 GHz) | 2.51 | 2.53 | 2.64 | 2.49 | 2.65 | 2.74 | 2.58 | 2.55 |
| product | Df (10 GHz) | 0.0023 | 0.0019 | 0.0014 | 0.0020 | 0.0025 | 0.0017 | 0.0036 | 0.0032 |
| | Tg [° C.] | 184 | 177 | 160 | 202 | 211 | — | 172 | 238 |

### Summary of Result

In Examples 101 to 106, a cured film product was obtained using a curable polymer as a copolymer containing a structural unit (UX) containing no polar atoms and a monovinyl aromatic compound-derived structural unit (UY).

In Example 107, a cured film product was obtained using a curable polymer as a copolymer containing a structural unit (UX) containing polar atoms and a monovinyl aromatic compound-derived structural unit (UY).

In Example 201, a cured film product was obtained using only a modified PPE oligomer containing no structural unit (UX).

In Examples 101 to 106, the dielectric dissipation factor (D_{f}) under high-frequency conditions could be effectively reduced as compared with Example 201. In these Examples, it was possible to obtain a cured film product with effectively reduced dielectric dissipation factor (D_{f}) under high-frequency conditions and sufficiently high glass transition temperature (Tg).

In Example 107, the dielectric dissipation factor (D_{f}) under high-frequency conditions was at the same level as that in Example 201, and was at a practical level. In this example, it was possible to obtain a cured film product with sufficiently low dielectric dissipation factor (D_{f}) under high-frequency conditions and sufficiently high glass transition temperature (Tg).

### Example 301

Curable polymer (P11) synthesized in Example 1, the modified polyphenylene ether (PPE) oligomer (SA9000), dicumyl peroxide (DCP) as a radical initiator, spherical silica as an inorganic filler and toluene were mixed in a mass ratio of 50:50:1:100:100 and stirred at room temperature to prepare a curable polymer composition (varnish).

The resulting curable polymer composition (varnish) was impregnated into a glass cloth (E glass, #2116) as a fibrous substrate, followed by heating at 130° C. for five minutes to semi-cure the curable polymer composition, thereby obtaining a prepreg.

Two sheets of the obtained prepreg were stacked and sandwiched between a pair of copper foils, and the resulting temporary multilayer body was heated and pressed under the conditions of 200° C., 1.5 hours, and 3 MPa to produce a metal clad laminate.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A curable polymer comprising one or more type(s) of structural units (UX) represented by the following formula and which is for production of a prepreg, a metal clad laminate or a wiring board: 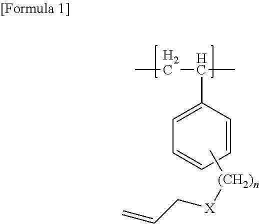
wherein X is a single bond or an oxygen atom; the benzene ring optionally has a substituent other than the substituent in the above formula; and n is an integer of 0 or more.

2. The curable polymer according to claim 1, wherein the curable polymer contains one or more type(s) of structural units (UX) and one or more type(s) of monovinyl aromatic compound-derived structural units (UY).

3. The curable polymer according to claim 1, wherein a content of the one or more type(s) of structural units (UX) based on a total amount of 100% by mol of all the structural units is 1 to 90% by mol.

4. The curable polymer according to claim 1, wherein X is a single bond.

5. The curable polymer according to claim 1, wherein n is 1 to 18.

6. A curable composition comprising: the curable polymer according to claim 1.

7. The curable composition according to claim 6, further comprising other curable compound having one or more type(s) of polymerizable functional groups.

8. A prepreg comprising: a fibrous substrate; and a semi-cured product or cured product of the curable composition according to claim 6.

9. A multilayer body comprising: a substrate; and a curable composition layer comprising the curable composition according to claim 6.

10. A multilayer body comprising: a substrate; and a (semi-) cured product-containing layer comprising a semi-cured product or cured product of the curable composition according to claim 6.

11. A metal clad laminate comprising: an insulating layer comprising a cured product of the curable composition according to claim 6; and metal foil.

12. A wiring board comprising: an insulating layer comprising a cured product of the curable composition according to claim 6; and wiring.
